(19) United States
(12) Patent Application Publication
(10) Pub. No.: US 2023/0411889 A1
(43) Pub. Date: Dec. 21, 2023

(54) FLEXIBLE CONTACTOR AND METHOD OF MANUFACTURING THE SAME

(71) Applicant: WITHMEMS CO., LTD., Hwaseong-si Gyeonggi-do (KR)

(72) Inventors: Hwang Sub KOO, Suwon-si Gyeonggi-do (KR); Jong Koon PARK, Yongin-si Gyeonggi-do (KR); Ki Sang YUN, Hwaseong-si Gyeonggi-do (KR); Kyung Ho KIM, Yongin-si Gyeonggi-do (KR)

(73) Assignee: WITHMEMS CO., LTD., Hwaseong-si Gyeonggi-do (KR)

(21) Appl. No.: 18/242,074

(22) Filed: Sep. 5, 2023

Related U.S. Application Data
(63) Continuation of application No. PCT/KR2022/003889, filed on Mar. 21, 2022.

(30) Foreign Application Priority Data
Mar. 5, 2021 (KR) 10-2021-0029377

(51) Int. Cl. H01R 13/24; G01R 1/067

(52) U.S. Cl. CPC H01R 13/2414; G01R 1/06716; H01R 2201/20; G01R 31/2863

(57) ABSTRACT

A flexible contactor that electrically connects a pad of an inspection target object with a pad of an inspection device includes, a first elastic part configured to contain a first conductive particle and be formed elastically deformable; and a second elastic part, which is connected in parallel to the first elastic part in a longitudinal direction, configured to contain a second conductive particle and be formed elastically deformable. The first elastic part and the second elastic part are different from each other in at least one of physical properties including hardness, Young's modulus, and resistivity.

### CROSS-REFERENCE TO RELATED APPLICATIONS

This application is a continuation of International Application No. PCT/KR2022/003889 filed on Mar. 21, 2022, which claims priority to Korean Patent Application No. 10-2021-0029377 filed on Mar. 5, 2021, the entire contents of which are herein incorporated by reference.

### TECHNICAL FIELD

The present disclosure relates to flexible contactor that electrically connects a pad of an inspection target object with a pad of an inspection device, and a method of manufacturing the same.

### BACKGROUND

When inspecting a performance of a semiconductor device, an interconnect structure configured to electrically connect a terminal of a pad of an inspection target object with a terminal of a pad of an inspection device is used. The interconnect structure mounted on the inspection device is in contact with the pad of the inspection target object, transmits electricity to the pad of the inspection target object, and sorts defective pads of the inspection target object according to the returned signal.

The interconnect structure can electrically transmit an inspection signal while ensuring contact with a terminal of the pad of the inspection target object by elastic force. A conventional interconnect structure uses a pogo pin, and the pogo pin includes a hollow pipe, a spring located inside the pipe, and at least one terminal which is supported by the spring and the pipe and is movable. With this configuration, the pogo pin can electrically transmit an inspection signal while ensuring contact with the terminal of the pad of the inspection target object by the elastic force.

However, the pogo pin also needs to be manufactured smaller in response to a trend of miniaturizing a pitch between terminals of the pads of the inspection target object. Also, there is a need for a design capable of improving the precision of a test operation while responding to the miniaturization trend, and suppressing deformation or damage caused by repeated uses.

### SUMMARY OF THE INVENTION

### Problems to be Solved by the Invention

One object of the present disclosure is to provide a flexible contactor configured to be able to design properties appropriate for mechanical and electrical connection and inspection in various ways according to different parts.

Another object of the present disclosure is to provide a method of manufacturing a flexible contactor configured to be able to design shapes appropriate for connection and inspection in various ways according to different parts, and also to easily manufacture a long shape.

However, the problems to be solved by the present disclosure are not limited to the above-described problems, and there may be other problems to be solved.

### Means for Solving the Problems

To achieve the objects of the present disclosure, a flexible contactor that electrically connects a pad of an inspection target object with a pad of an inspection device includes, a first elastic part configured to contain a first conductive particle and be formed to be elastically deformable; and a second elastic part which is connected in parallel to the first elastic part in a longitudinal direction, contains a second conductive particle and is formed to be elastically deformable, and wherein the first elastic part and the second elastic part are different from each other in at least one of physical properties including hardness, Young's modulus, and resistivity.

To achieve the objects of the present disclosure, a method of manufacturing a flexible contactor that electrically connects a pad of an inspection target object with a pad of an inspection device includes, filling a first receptor of a first mold with a first elastic part in a liquid phase containing a first conductive particle; filling a second receptor of a second mold corresponding to the first receptor with a second elastic part in a liquid phase containing a second conductive particle; aligning a magnetic flux concentration member including magnetic pads at positions corresponding to the first receptor and the second receptor, in the first mold and the second mold which are aligned with each other; hardening the first elastic part and the second elastic part at a predetermined pressure and predetermined temperature; and separating a flexible contactor integrally formed with the first elastic part and the second elastic part, from the first mold and the second mold.

The above-described technical solutions are provided by way of illustration only and should not be construed as liming the present disclosure. Besides the above-described exemplary embodiments, there may be additional embodiments described in the drawings and the detailed description.

### Effects of the Invention

According to any one of the above-described technical solutions of the present disclosure, hardness, Young's modulus, resistivity, and conductive particle density appropriate for mechanical and electrical connection and inspection can be designed in various way according to different parts.

Also, according to the present disclosure, the flexible contactor can be configured to design shapes appropriate for connection and inspection in various ways according to different parts, and to easily manufacture to a long shape. That is, the length of the contactor can be increased by stacking a several layers of the elastic parts, and thus, the contactor can be effectively manufactured to a long shape while a cross-sectional area is finely maintained.

Therefore, the flexible contactor according to the present disclosure can improve the precision of a test operation while responding to the miniaturization trend, and suppress deformation or damage caused by repeated uses.

### BRIEF DESCRIPTION OF THE DRAWINGS

FIG. 1 is a diagram illustrating a flexible contactor according to an embodiment of the present disclosure.

FIG. 2A is a diagram illustrating a flexible contactor according to another embodiment of the present disclosure.

FIG. 2B is a diagram illustrating a flexible contactor according to another embodiment of the present disclosure.

FIG. 3A is a diagram illustrating a flexible contactor according to another embodiment of the present disclosure.

FIG. 3B is a diagram illustrating a flexible contactor according to another embodiment of the present disclosure.

FIG. 4 is a diagram illustrating a flexible contactor and a housing according to yet another embodiment of the present disclosure.

FIG. 5 is a diagram illustrating a flexible contactor and a housing according to yet another embodiment of the present disclosure.

FIG. 6 is a diagram illustrating a flexible contactor and a housing according to yet another embodiment of the present disclosure.

FIG. 7 is a diagram illustrating a flexible contactor and a housing according to yet another embodiment of the present disclosure.

FIG. 8 is a diagram illustrating a flexible contactor and a housing according to yet another embodiment of the present disclosure.

FIG. 9 is a flowchart showing a method of manufacturing a flexible contactor according to an embodiment of the present disclosure.

FIG. 10 is a diagram illustrating steps of the method of manufacturing a flexible contactor shown in FIG. 9.

FIG. 11 is a diagram illustrating steps of the method of manufacturing a flexible contactor shown in FIG. 9.

FIG. 12 is a diagram illustrating steps of the method of manufacturing a flexible contactor shown in FIG. 9.

FIG. 13 is a diagram illustrating steps of the method of manufacturing a flexible contactor shown in FIG. 9.

FIG. 14 is a diagram illustrating steps of the method of manufacturing a flexible contactor shown in FIG. 9.

### DETAILED DESCRIPTION

Hereinafter, example embodiments will be described in detail with reference to the accompanying drawings so that the present disclosure may be readily implemented by a person with ordinary skill in the art. However, it is to be noted that the present disclosure is not limited to the example embodiments but can be embodied in various other ways. In the drawings, parts irrelevant to the description are omitted in order to clearly explain the present invention, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element. Further, it is to be understood that the term “comprises or includes” and/or “comprising or including” used in the document means that one or more other components, steps, operation and/or existence or addition of elements are not excluded in addition to the described components, steps, operation and/or elements unless context dictates otherwise and is not intended to preclude the possibility that one or more other features, numbers, steps, operations, components, parts, or combinations thereof may exist or may be added.

Hereinafter, embodiments of the present disclosure will be described in detail with reference to the accompanying drawings.

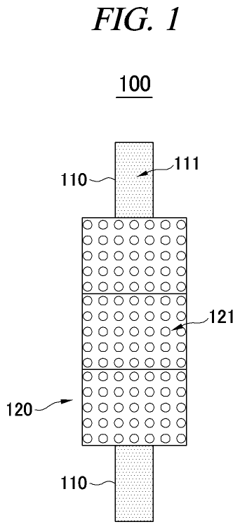

FIG. 1 is a diagram illustrating a flexible contactor according to an embodiment of the present disclosure. Referring to FIG. 1, a flexible contactor 100 according to an embodiment of the present disclosure may include a first elastic part 110 and a second elastic part 120. The first elastic part 110 may contain a first conductive particle 111 and may be formed to be elastically deformable, and the second elastic part 120 may be connected in parallel to the first elastic part 110 in a longitudinal direction, may contain a second conductive particle 121 and may be formed to be elastically deformable.

The first elastic part 110 and the second elastic part 120 may include various types of polymer materials. The first elastic part 110 and the second elastic part 120 may be formed of diene type rubber such as silicone, polybutadiene, polyisoprene, SBR, NBR, and hydrogen compounds thereof, or may be formed of a block copolymer such as a styrene butadiene block copolymer, a styrene isoprene block copolymer, and hydrogen compounds thereof. Alternatively, the first elastic part 110 and the second elastic part 120 may be formed of chloroprene, urethane rubber, polyethylene-based rubber, epichlorohydrin rubber, an ethylene-propylene copolymer, an ethylene propylene diene copolymer, and the like.

Herein, the first elastic part 110 and the second elastic part 120 may be different from each other in at least one of physical properties including hardness, Young's modulus, and resistivity. For example, the hardness and the Young's modulus of the first elastic part 110 to be in direct contact with a terminal of a pad of an inspection target object and a terminal of a pad of an inspection device may be designed to be higher than those of the second elastic part 120 interposed between the first elastic parts 110. Thus, it is possible to improve the precision of a test operation and also possible to suppress deformation or damage of both end portions caused by repeated uses.

The first conductive particle 111 and the second conductive particle 121 according to an embodiment of the present disclosure may be different from each other in at least one of material and size. For example, the first elastic part 110 containing the first conductive particle 111 and the second elastic part 120 containing the second conductive particle 121 may be designed to have different properties from each other depending on the material and size of a conductive particle contained therein.

For example, the first conductive particle 111 and the second conductive particle 121 may be formed of a single conductive metal material, such as iron, copper, zinc, chromium, nickel, silver, cobalt, and aluminum, or an alloy of two or more of them, which are ferromagnetic materials. The first conductive particle 111 and the second conductive particle 121 may be prepared by coating the surface of a core metal with a highly conductive metal, such as gold, silver, rhodium, palladium, platinum, or silver and gold, silver and rhodium, and silver and palladium. The conductive particle 121 may further include a MEMS tip, flake, wire rod, carbon nanotube (CNT), graphene, etc. in order to improve conductivity.

Regarding the material of the conductive particle, the flexible contactor 100 according to an embodiment of the present disclosure may employ a nickel particle for effective alignment of conductive particles or may employ a copper particle if necessary to improve electrical conductivity. The flexible contactor 100 according to an embodiment of the present disclosure may also employ a silica-coated particle for weight lightening. In view of these characteristics, the flexible contactor 100 according to the present disclosure may select the first conductive particle 111 in the first elastic part 110 and the second conductive particle 121 in the second elastic part 120 to be different from each other depending on the position (layer).

Also, regarding the size of the conductive particle, conductive particles having a greater size are generally easy to process and excellent in terms of electrical conductivity. However, conductive particles having a smaller size can be relatively uniformly distributed even in a member having a fine diameter and thus improve the hardness or Young's modulus of the member. In view of these characteristics, the flexible contactor 100 according to the present disclosure may include small sized particles distributed at a position (layer) requiring a high hardness.

A density of the first conductive particles 111 according to an embodiment of the present disclosure in the first elastic part 110 is different from a density of the second conductive particles 121 in the second elastic part 120. For example, even if the first conductive particle 111 and the second conductive particle 121 are equal to each other in size, the density of the first conductive particles 111 in the first elastic part 110 may be designed to be different from the density of the second conductive particles 121 in the second elastic part 120, and, thus, the first elastic part 110 and the second elastic part 120 may be designed to be different from each other in hardness or Young's modulus.

Referring to FIG. 1, the flexible contactor 100 according to an embodiment of the present disclosure may include the first elastic part 110 and the second elastic part 120 different from each other in cross-sectional shape as viewed from a longitudinal direction. That is, the first elastic part 110 may be designed to have a smaller cross-sectional area as viewed from the longitudinal direction than the second elastic part 120. Both end portions in the longitudinal direction are to be in contact with the pad of the inspection target object or the inspection device, and, thus, small sized particles are placed in the first elastic part 110 to increase the hardness. The first elastic parts 110 at the both end portions in the longitudinal direction may be formed to have a smaller diameter, i.e., a smaller cross-sectional area and thus may correspond to pads with a fine pitch.

Specifically, the both end portions may be formed to have a smaller diameter than a central portion. Thus, it is possible to avoid interference with peripheral components and also possible to minimize leakage current between adjacent pins. Further, the flexible contactor 100 of the present disclosure includes the first elastic parts 110 containing the first conductive particle 111 at the both end portions and thus can make an elastic contact with a pad or the like, as compared to a case where the both end portions are formed of a metallic material. Therefore, it is possible to suppress damage of a structure, such as a pad or the like.

On the other hand, the second elastic part 120 placed at the central portion where no interference from exists may be formed to have a greater diameter, i.e., a greater cross-sectional area. Thus, it is possible to overcome contact instability in electrical connection between the pad of the inspection target object and the pad of the inspection device. That is, the second elastic part 120 containing large sized particles may be placed at the central portion of the flexible contactor 100 to secure electrical conductivity required during a test.

As described above, in the flexible contactor 100 according to an embodiment of the present disclosure, components, such as the first elastic part 110 and the second elastic part 120, having different physical properties from each other may be stacked to satisfy various design requirements for a probe pin. That is, the first elastic part 110 and the second elastic part 120 different from each other in physical properties may be placed respectively corresponding to a part (layer) requiring an excellent hardness and a part (layer) where elastic deformation is allowed.

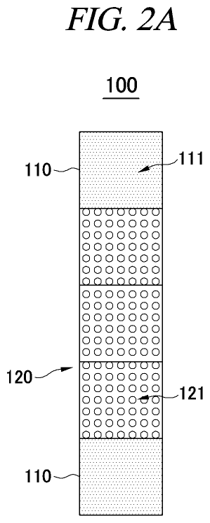

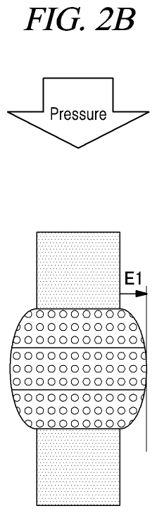

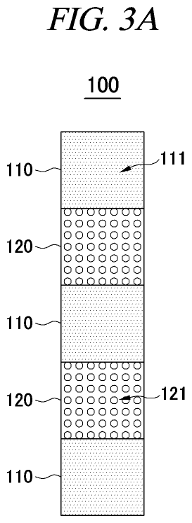

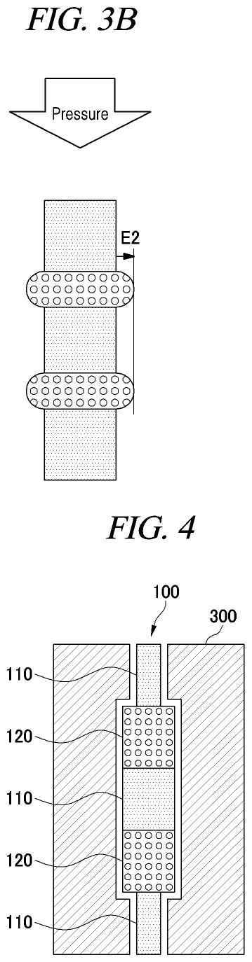

FIG. 2 and FIG. 3 are diagrams each illustrating a flexible contactor according to another embodiment of the present disclosure. Referring to FIG. 2A, the first elastic part 110 is connected to each of both end portions of the flexible contactor 100 in a longitudinal direction, and a size of the first conductive particle 111 is smaller than a size of the second conductive particle 121.

For example, the flexible contactor 100 illustrated in FIG. 2 place the first elastic part 110 containing the first conductive particle 111 having relatively small particle, at each of the both end portions in the longitudinal direction, and, thus, the flexible contactor 100 can secure hardness or Young's modulus required for contact with the pad of the inspection target object. Also, the flexible contactor 100 illustrated in FIG. 2 includes the second elastic part 120 containing the second conductive particle 121 relatively large particle between the first elastic parts 110, and, thus, the flexible contactor 100 can secure electrical conductivity required during a test. That is, the flexible contactor 100 illustrated in FIG. 2 includes the first elastic part 110 containing small sized particles at the both end portions to be in direct contact with a terminal of each pad, and the second elastic part 120 containing large sized particles between the first elastic parts 110, and, thus, the flexible contactor 100 can secure all of hardness, Young's modulus, and electrical conductivity required for each part during a test.

Referring to FIG. 3, in the flexible contactor 100 according to an embodiment of the present disclosure, any one of the first elastic part 110 and the second elastic part 120 may be spaced apart from each other with the other one interposed therebetween in a longitudinal direction. For example, each of the first elastic parts 110 or the second elastic parts 120 may be stacked a plurality of times while being spaced apart from each other. That is, the first elastic parts 110 and the second elastic parts 120 can be alternately stacked into several layers in the longitudinal direction.

The flexible contactor 100 illustrated in FIG. 3 includes the first elastic parts 110 and the second elastic parts 120 which are alternately placed, and, thus, the position or size of an elastically deformable part can be adjusted in various ways. Therefore, the flexible contactor 100 including the first elastic parts 110 and the second elastic parts 120 which are alternately placed as illustrated in FIG. 3 has a smaller amount of deformation in a transverse direction (see FIG. 3B) than the flexible contactor 100 including the second elastic parts 120 all placed at a central portion as illustrated in FIG. 2. Thus, it is possible to improve the precision of a test operation while responding to the miniaturization trend.

That is, in the flexible contactor 100 according to the present disclosure, a plurality of elastically deformable parts is dispersed to a plurality of positions, and, thus, when the flexible contactor 100 is compressed during a test, the volume expansion in a cross-sectional direction (transverse direction) can be minimized. Specifically, referring to FIG. 2B and FIG. 3B, when the flexible contactor 100 is compressed during a test, the flexible contactor 100 illustrated in FIG. 3 may have a smaller amount of deformation than the flexible contactor 100 illustrated in FIG. 2. Referring to FIG. 3B, an amount of deformation E2 which is the amount of volume expansion depending on compression applied may be smaller than an amount of deformation E1 illustrated in FIG. 2B.

As described above, the flexible contactor 100 having a minimized amount of deformation can be closely coupled to a housing that supports the flexible contactor 100 in the transverse direction, and an assembly tolerance with respect to the housing can be effectively managed. Therefore, it is possible to improve the precision of a test operation and also possible to suppress deformation or damage caused by repeated uses.

FIG. 4 to FIG. 8 are diagrams each illustrating a flexible contactor and a housing according to yet another embodiment of the present disclosure. Referring to FIG. 4, the flexible contactor 100 according to an embodiment of the present disclosure includes the first elastic parts 110 containing the first conductive particle 111 having a relatively small particle at the both end portions in the longitudinal direction and at the central portion, and, thus, it is possible to improve the hardness of the flexible contactor 100.

Since the first elastic part 110 is placed at the central portion according to an embodiment of the present disclosure, the flexible contactor 100 with the improved hardness may decrease in amount of deformation in the transverse direction when it is in contact with the terminal of the pad of the inspection target object. Therefore, it is possible to improve the precision of a test operation while responding to the miniaturization trend.

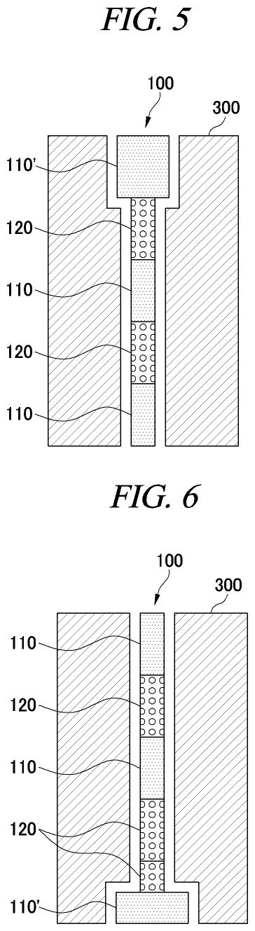

Referring to FIG. 5, the flexible contactor 100 according to an embodiment of the present disclosure is designed to be supported only in one direction (e.g., downwards only) inside a housing 300, and may include a first elastic part 110′ placed at one end portion (e.g., an upper end portion) in the longitudinal direction and having a greater cross-sectional area than the first elastic parts 110 and the second elastic parts 120. For example, the flexible contactor 100 illustrated in FIG. 5 may be designed such that the first elastic part 110′ to be in contact with the terminal of the pad of the inspection target object has a greater area than the first elastic parts 110 and the second elastic parts 120. Therefore, in the flexible contactor 100 according to the present disclosure, the first elastic part 110′ to be in contact with the terminal of the pad of the inspection target object is increased in cross-sectional area, i.e., diameter, and, thus, a contact area is increased. Thus, it is possible to overcome instability in contact with the terminal of the pad of the inspection target object.

Referring to FIG. 6, the flexible contactor 100 according to an embodiment of the present disclosure is designed to be supported only in the other direction (e.g., upwards only) inside the housing 300, and may include the first elastic part 110′ placed at the other end portion (e.g., a lower end portion) in the longitudinal direction and having a greater cross-sectional area than the first elastic parts 110 and the second elastic parts 120. For example, the flexible contactor 100 illustrated in FIG. 6 may be designed such that the first elastic part 110′ to be in contact with the terminal of the pad of the inspection device has a greater area than the first elastic parts 110 and the second elastic parts 120. Therefore, in the flexible contactor 100 according to the present disclosure, the first elastic part 110′ to be in contact with the terminal of the pad of the inspection device is increased in cross-sectional area, i.e., diameter, and, thus, a contact area is increased. Thus, it is possible to overcome instability in contact with the terminal of the pad of the inspection device.

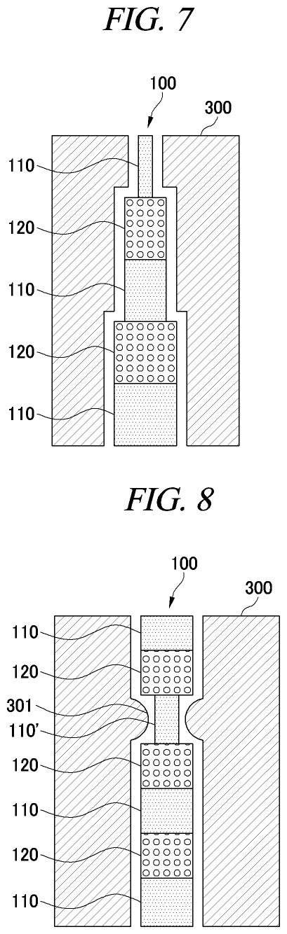

Referring to FIG. 7, the flexible contactor 100 according to an embodiment of the present disclosure may be designed such that the first elastic parts 110 and the second elastic parts 120 are alternately stacked while forming a step difference. For example, the flexible contactor 100 illustrated in FIG. 7 may be designed such that the first elastic parts 110 and the second elastic parts 120 are alternately stacked and gradually decreased in transverse cross-sectional area, i.e., diameter in one direction while forming a step difference. Therefore, the flexible contactor 100 according to the present disclosure may gradually absorb and alleviate impact applied by contact with the terminal of the pad of the inspection target object and the terminal of the pad of the inspection device.

Referring to FIG. 8, the flexible contactor 100 according to an embodiment of the present disclosure may include the first elastic part 110 or the second elastic part 120 placed on a certain layer between the both end portions in the longitudinal direction and having a smaller cross-sectional area, i.e., a smaller diameter than the first elastic parts 110 and the second elastic parts 120. For example, the flexible contactor 100 illustrated in FIG. 8 may be designed such that the first elastic part 110′ placed on the certain layer between the both end portions in the longitudinal direction has a smaller cross-sectional area than the first elastic parts 110 and the second elastic parts 120. Therefore, the flexible contactor 100 illustrated in FIG. 8 may be assembled by insertion into the housing 300 in the longitudinal direction, and, thus, the assembly supported in both directions can be easily manufactured. In this case, a round portion 301 corresponding to a certain layer protrudes from the housing 300 and enables the flexible contactor 100 to be easily inserted.

The flexible contactor 100 illustrated in FIG. 4 to FIG. 8 includes the first elastic parts 110 and the second elastic parts 120 which are alternately stacked and thus can secure sufficient hardness, Young's modulus and electrical conductivity required during a test and improve the precision of a test operation. Also, in the flexible contactor 100 illustrated in FIG. 4 to FIG. 8, a plurality of elastically deformable parts is dispersed to a plurality of positions, and, thus, when the flexible contactor 100 is compressed during a test, the volume expansion can be minimized. Therefore, the flexible contactor 100 illustrated in FIG. 4 to FIG. 8 can be closely coupled to the housing 300, and an assembly tolerance with respect to the housing 300 can be effectively managed.

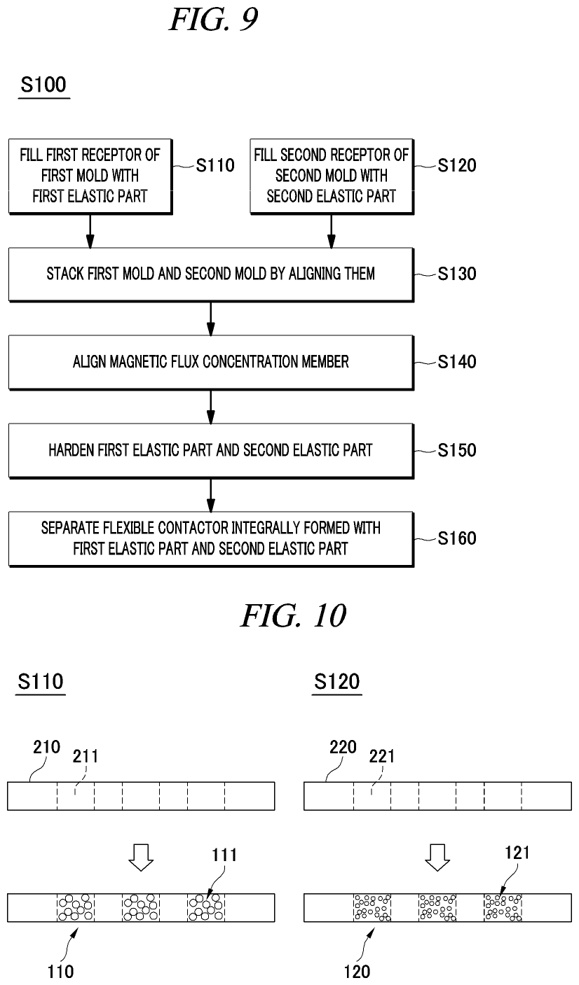

Meanwhile, the first elastic part 110 and the second elastic part 120 according to an embodiment of the present disclosure may be hardened by a phase change and integrally formed with each other. For example, the first elastic part 110 and the second elastic part 120 may be integrally formed with each other. A method of manufacturing the flexible contactor 100 in which the first elastic part 110 and the second elastic part 120 are integrally formed with each other will be described in more detail with reference to FIG. 9.

FIG. 9 is a flowchart showing a method of manufacturing a flexible contactor according to an embodiment of the present disclosure, and FIG. 10 to FIG. 14 are diagrams illustrating respective steps of the method of manufacturing a flexible contactor shown in FIG. 9. The method of manufacturing a flexible contactor (S100) illustrated in FIG. 9 includes the steps time-sequentially performed according to the embodiment illustrated in FIG. 1 to FIG. 8. Therefore, the above descriptions of the steps may also be applied to the method of manufacturing a flexible contactor (S100) according to the embodiment illustrated in FIG. 1 to FIG. 8 even though they are omitted hereinafter.

Referring to FIG. 10, the method of manufacturing a flexible contactor (S100) may fill a first receptor 211 of a first mold 210 with the first elastic part 110 in a liquid phase containing the first conductive particle 111 in a step S110, and fill a second receptor 221 of a second mold 220 corresponding to the first receptor 211 with the second elastic part 120 in a liquid phase containing the second conductive particle 121 in a step S120. Herein, the first mold 210 and the second mold 220 are casts formed of metals or resins for manufacturing the flexible contactor 100. For example, the first mold 210 and the second mold 220 may be formed of metals or resins which are not magnetic. For example, the first mold 210 and the second mold 220 may be formed of aluminum (Al) or Torlon.

In the step S110, the first elastic part 110 and the second elastic part 120 may contain the first conductive particle 111 and the second conductive particle 121. The first conductive particle 111 and the second conductive particle 121 may be aligned in a longitudinal direction of the first elastic part 110 and the second elastic part 120. The first conductive particle 111 and the second conductive particle 121 may make a contact with each other to impart conductivity to the first elastic part 110 and the second elastic part 120 in the longitudinal direction. When the first elastic part 110 and the second elastic part 120 are compressed by a pressure in the longitudinal direction to inspect the inspection target object which is an electrical component, the first conductive particle 111 and the second conductive particle 121 may get closer to each other and electrical conductivity of the first elastic part 110 and the second elastic part 120 may increase in the longitudinal direction.

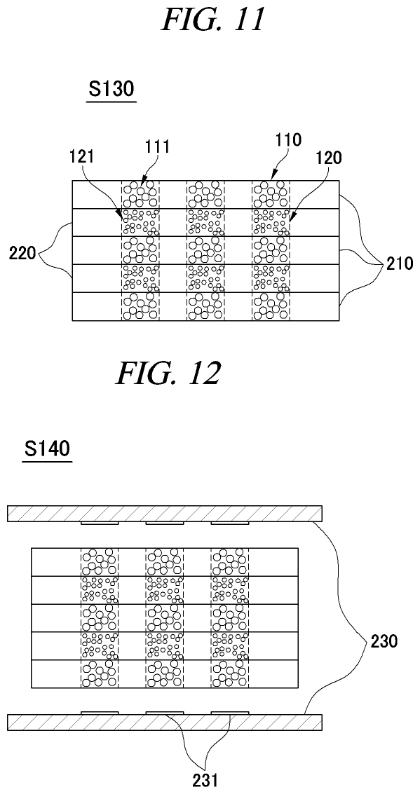

Referring to FIG. 11, the method of manufacturing a flexible contactor (S100) may stack the first mold and the second mold by aligning them with each other in a step S130. For example, in the step S130, a plurality of first elastic parts 110 and a plurality of second elastic parts 120 may be aligned to be alternately stacked, and the first receptor 211 and the second receptor 221 may have various thicknesses or cross-sectional shapes depending on design requirements.

As illustrated in FIG. 10 and FIG. 11, in the method of manufacturing a flexible contactor (S100) according to the present disclosure, the first elastic part 110 and the second elastic part 120 are filled (S110, S120), and the first mold 210 and the second mold 220 may be aligned with each other (S130). Alternatively, in the method of manufacturing a flexible contactor (S100) according to the present disclosure, the first receptor 211 of the first mold 210 may be filled with the first elastic part 110 (S110), the second mold 220 may be aligned or stacked with the first mold 210 (S130), and the second receptor 221 may be filled with the second elastic part 120 (S120).

Referring to FIG. 12, in a step S140, a magnetic flux concentration member 230 including magnetic pads 231 may be aligned at positions corresponding to the first receptor 211 and the second receptor 221, in the first mold 210 and the second mold 220 which are aligned with each other. For example, the magnetic flux concentration member 230 may include a plurality of magnetic pads 231 placed at predetermined intervals on the member. Herein, the magnetic pads 231 may be formed of a magnetic material, such as nickel (Ni), a nickel-cobalt alloy (NiCo), and iron (Fe). In this case, the magnetic flux concentration member 230 may be formed of a ferrimagnetic material to induce the concentration of magnetic flux on the magnetic pads 231.

In the step S140, the magnetic flux concentration member 230 may come in close contact with the first mold 210 or the second mold 220 to close the first receptor 211 or the second receptor 221 by the magnetic pads 231. For example, the magnetic flux concentration member 230 may be brought into close contact with an upper end and a lower end of the first mold 210 in which the first receptor 211 is filled with the first elastic part 110 or the second mold 220 in which the second receptor 221 is filled with the second elastic part 120. The magnetic pads 231 may be configured to concentrate magnetic flux.

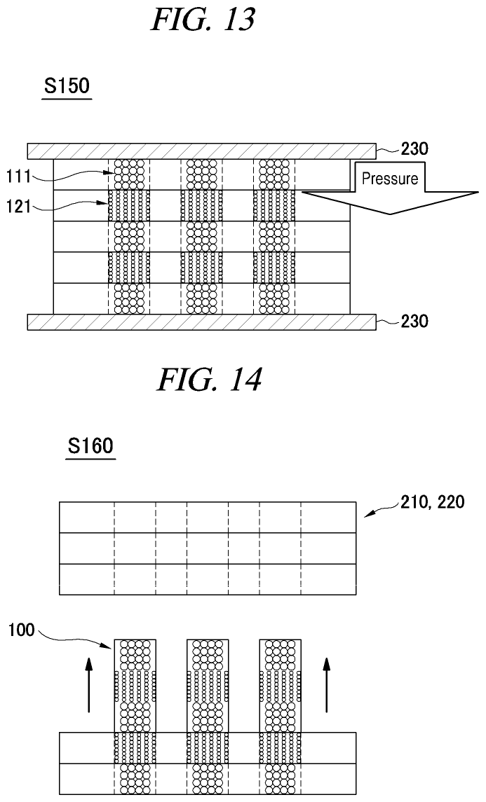

Referring to FIG. 13, the method of manufacturing a flexible contactor (S100) may harden first elastic part 110 and the second elastic part 120 at a predetermined pressure and predetermined temperature in a step S150. In the step S150 of hardening the first elastic part 110 and the second elastic part 120, at least one of heat and pressure may be applied to the first elastic part 110 and the second elastic part 120 by the magnetic flux concentration member 230.

For example, the first elastic part 110 and the second elastic part 120 may be integrally formed with each other through a phase change caused by at least one of the applied heat and pressure. In the step S150, heat and pressure may be applied to the magnetic flux concentration member 230 in close contact with the first mold 210 or the second mold 220 to harden the first elastic part 110 or the second elastic part 120.

Referring to FIG. 14, the method of manufacturing a flexible contactor (S100) may separate the flexible contactor 100 including the first elastic part 110 and the second elastic part 120 integrally formed with each other, from the first mold 210 and the second mold 220 in a step S160. For example, in the step S160, the magnetic flux concentration member 230 in close contact with the first mold 210 or the second mold 220 may be separated from the first mold 210 or the second mold 220. Then, the flexible contactor 100 integrally formed with the first elastic part 110 and the second elastic part 120 may be separated from the first mold 210 and the second mold 220.

In the method of manufacturing a flexible contactor (S100) according to the present disclosure, a plurality of molds including the first mold 210 and the second mold 220 may be used to manufacture a multilayer flexible contactor having a plurality of layers including the first elastic part 110 and the second elastic part 120. The method of manufacturing a flexible contactor (S100) according to the present disclosure can manufacture a contactor in which the first elastic part 110 and the second elastic part 120 have the same physical property, and even if the entire contactor has a single property, the contactor may include layers different from each other in shape and may be manufactured lengthily with a fine thickness, as compared to conventional contactors.

The method of manufacturing a flexible contactor (S100) according to the present disclosure can remove a plurality of stacked first molds 210 and second molds 220 one by one, separate the first molds 210 and second molds 220 so as not to damage the manufactured flexible contactor 100, and separate the flexible contactor 100 from the first mold 210 and the second mold 220 more easily.

In the descriptions above, the steps S110 to S160 may be divided into additional steps or combined into fewer steps depending on an embodiment. In addition, some of the steps may be omitted and the sequence of the steps may be changed if necessary.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A flexible contactor that electrically connects a pad of an inspection target object with a pad of an inspection device, comprising,
a first elastic part configured to contain a first conductive particle and be formed elastically deformable; and
a second elastic part, which is connected in parallel to the first elastic part in a longitudinal direction, configured to contain a second conductive particle and be formed elastically deformable,
wherein the first elastic part and the second elastic part are different from each other in at least one of physical properties including hardness, Young's modulus, and resistivity.

2. The flexible contactor of claim 1,
wherein the first conductive particle and the second conductive particle are different from each other in at least one of material and size.

3. The flexible contactor of claim 1,
wherein a density of the first conductive particles in the first elastic part is different from a density of the second conductive particles in the second elastic part.

4. The flexible contactor of claim 1,
wherein any one of the first elastic part and the second elastic part is spaced apart from each other with the other one interposed therebetween in the longitudinal direction.

5. The flexible contactor of claim 1,
wherein the first elastic part and the second elastic part are different from each other in cross-sectional shape as viewed from the longitudinal direction.

6. The flexible contactor of claim 1,
wherein the first elastic part is connected to each of both end portions of the flexible contactor in the longitudinal direction, and
wherein a size of the first conductive particle is smaller than wherein a size of the second conductive particle.

7. The flexible contactor of claim 1,
wherein the first elastic part and the second elastic part are hardened by a phase change and integrally formed with each other.

8. A method of manufacturing a flexible contactor that electrically connects a pad of an inspection target object with a pad of an inspection device, comprising,
filling a first receptor of a first mold with a first elastic part in a liquid phase containing a first conductive particle;
filling a second receptor of a second mold corresponding to the first receptor with a second elastic part in a liquid phase containing a second conductive particle;
aligning a magnetic flux concentration member including magnetic pads at positions corresponding to the first receptor and the second receptor, in the first mold and the second mold which are aligned with each other;
hardening the first elastic part and the second elastic part at a predetermined pressure and predetermined temperature; and
separating the flexible contactor integrally formed with the first elastic part and the second elastic part, from the first mold and the second mold.

9. The method of manufacturing the flexible contactor of claim 8, further comprising,
aligning the first mold and the second mold with each other,
wherein the aligning the first mold and the second mold with each other is performed after the filling the first receptor and the filling the second receptor, or is performed after the filling the first receptor and before the filling the second receptor.

10. The method of manufacturing the flexible contactor of claim 8,
wherein in the hardening the first elastic part and the second elastic part, at least one of heat and pressure is applied to the first elastic part and the second elastic part by the magnetic flux concentration member.
